(19) United States
(12) Patent Application Publication
(10) Pub. No.: US 2025/0233041 A1
(43) Pub. Date: Jul. 17, 2025

(54) COOLING DEVICE

(71) Applicant: Miba Sinter Austria GmbH, Laakirchen (AT)

(72) Inventors: Jürgen BAUER, Altmünster (AT); Manuel POHN, Zell am Pettenfirst (AT)

(73) Assignee: Miba Sinter Austria GmbH, Laakirchen (AT)

(21) Appl. No.: 18/991,901

(22) Filed: Dec. 23, 2024

(30) Foreign Application Priority Data
Jan. 16, 2024 (AT) A50021/2024

(51) Int. Cl. H01L 23/367

(52) U.S. Cl. CPC H01L 23/3677

(57) ABSTRACT

A cooling device for cooling a component includes a base element with a first surface and a second surface opposite the first surface and forming a rear side, and with a cooling structure having cooling elements that is arranged on the base element so as to protrude over the first surface. The rear side of the base element has a curved configuration and a prestress. Alternatively or additionally, at least one auxiliary element is arranged on the rear side to create a substance bonding between the cooling device and the component.

### CROSS REFERENCE TO RELATED APPLICATIONS

Applicant claims priority under 35 U.S.C. § 119 of Austrian Application No. A50021/2024 filed Jan. 16, 2024, the disclosure of which is incorporated by reference.

### BACKGROUND OF THE INVENTION

### 1. Field of the Invention

The invention relates to a cooling device for cooling components, comprising a base element with a first surface and a second surface opposite the first surface and forming a rear side, and with a cooling structure having cooling elements which is arranged on the base element so as to protrude over the first surface.

The invention also relates to a method for producing a cooling device comprising the steps of providing a material and configuring a cooling structure from the material.

### 2. Description of the Related Art

So-called power electronics components, such as power semiconductors, are well known from the state of the art. Such components are frequently used, for example in motor vehicles. It is also known that these components generate large amounts of heat during operation, which often needs to be dissipated using a cooling medium. A wide variety of coolers are known in the prior art for this purpose, including so-called pin fin heat sinks, which are surrounded by a cooling medium and thus transfer the heat from the pins to the cooling medium. DE 10 2019 108 106 A1 describes for example a cooler for a power semiconductor in an inverter, wherein the cooler is configured in two parts and comprises a base plate as a first part, which can be connected to the power semiconductor in a thermally conductive manner; a heat sink as a second part, which is arranged on the base plate, wherein the heat sink has at least one wave-shaped recess, which is formed continuously from a side of the heat sink facing away from the base plate to a side facing the heat sink; wherein the first and second parts are connected to one another and are coated with a layer, which protects both parts from electrochemical reduction.

DE 10 2018 216 859 A1 discloses a device for cooling components, including a first and a second base body; cylindrical and/or conical first cooling fins which are configured in the first base body and around which a coolant can flow, and cylindrical and/or conical second cooling fins which are configured in the second base body and around which the coolant can flow, the second base body being joined to the first base body in such a way that the second cooling fins come to lie between the first cooling fins without touching the first base body.

### SUMMARY OF THE INVENTION

The present invention is based on the object of improving the substance bonding of a cooling device to components to be cooled.

The object of the invention is solved in the cooling device mentioned at the beginning in that the rear side of the base element is configured with a curvature so that the base element has a prestress and/or in that at least one auxiliary element is arranged on the rear side for producing a substance bonding between the cooling device and the component.

The object of the invention is further solved by the method mentioned at the beginning, according to which it is provided that a sintering powder is used as the material, from which a green compact is produced by pressing, that the green compact is sintered to form a preform, and that the cooling structure in the form of cooling elements is produced from the preform by forming, for which purpose a part of the preform is pressed through a mold, and in that a rear side of the base element is produced in a prestressed configuration with a curvature and/or in that at least one auxiliary element is arranged on the rear side for the production of a substance bonding between the cooling device and the component.

The advantage of this is that the prestress or curvature of the base element can prevent distortion of the power electronics or the component to be connected to the cooling device that may occur during a soldering process or, conversely, deformation or distortion of the cooling device caused by the effect of temperature. This prevents a reduction in contact surface between the cooling device and the power electronics or the component and the associated drop in performance. Compared to other methods, the curvature and/or the at least one auxiliary element for the production of a substance bonding can be easily integrated into the existing process steps, so that no extra process step is required for their production, such as machining the contact surface of the base element to the power electronics or the component. With the help of the at least one of auxiliary element, the configuration of the substance bonding can also be better defined, which may also simply achieve a full-surface abutment between the cooling device and the power electronics or the component and thus an improved heat dissipation.

According to an embodiment variant of the invention, it may be provided that the curvature is a concave curvature of the base element in relation to the cooling elements, in particular that the base element has a plano-concave configuration. This makes it easier to place the cooling device on the component to be cooled in order to form the substance bonding, which in turn simplifies the connection process itself.

According to an embodiment variant of the invention, it may be provided that the concave curvature has several different radii of curvature, so that the cooling device can be better adapted to different substance bonding methods. At the same time, the cooling device may also only be prestressed (higher) in portions, which reduces the influence of prebending on the material of the cooling device.

According to a further embodiment variant of the invention, it is advantageous for the formation of a uniform layer thickness of a filler material for producing the substance bonding if the base element has the curvature with the smallest radius of curvature in opposite edge areas.

According to a further embodiment variant of the invention, it may be provided that the auxiliary element is a depression in the second surface of the base element. The depression may act as a “catcher” for the liquid filler material during the production of the substance bonding, so that excessive running of the filler material can be reduced or prevented. If necessary, the substance bonding can be limited to discrete areas of the cooling device or the component to be cooled.

To improve these effects, according to an embodiment variant it may be provided that the depression has a maximum depth of between 0.05 mm and 0.5 mm. Below 0.05 mm, the configuration of the depression is more susceptible to errors in the connection formation, as the depression may not be filled with the filler material. With a depth of more than 0.5 mm, the gap between the cooling device and the component in which the substance bonding is configured may change too much, so that a uniform connection layer may not be formed.

According to a further embodiment variant, in order to form a uniform connection layer of the filler material between the cooling device and the component, it may be provided that the auxiliary element is a protrusion on the second surface of the base element.

It may be advantageous if, according to an embodiment variant, the protrusion has a maximum height of between 0.05 mm and 0.5 mm. As with the depression, a height of less than 0.05 mm may be too small for the gap thickness to form a uniform connection layer. On the other hand, with a height of more than 0.5 mm, the connection layer may be too thick, which may impair heat dissipation. If a gap thickness is more than 0.5 mm, the liquid filler material may flow out of the connection area, creating the risk of an uneven connection layer.

According to a further embodiment variant of the invention, it may be provided that the base element and the cooling elements consist of a sinter material and that the cooling elements are produced by forming from the material of the base element. The advantage here is that the forming of the base element to the cooling elements means that no waste material is produced for their production, as is the case with machining, for example. In addition, all cooling elements of the cooling device can be produced at the same time, which may lead to a corresponding increase in productivity. The advantage for forming is that the preform, although it already has a corresponding strength due to sintering, is easier to form due to the pores compared to a solid material.

For the same reasons, it is advantageous if, according to a further embodiment variant of the invention, the auxiliary element or elements is/are manufactured in one piece with the base element by powder metallurgy. This means that no further process steps are required for their configuration.

According to an embodiment variant of the invention, it may be provided that the cooling elements are height-calibrated after the preform has been formed. It is thus possible with a simple method step to take into account a curvature of the abutment surface of the base element on the component, in particular the reduction of the curvature due to a reduction in stress during the production of the substance bonding and the effect of this on the height profile of the cooling structure.

To simplify the method and in particular to avoid machining of the base element, according to embodiment variants of the invention it may be provided that the curvature of the rear side of the base element is configured during the height calibration and/or that the auxiliary element is configured on the rear side of the base element for the production of a substance bonding during the forming of the preform. With the latter embodiment variant, the height calibration step can also be simplified, as there is no risk of crushing an existing structure for the auxiliary element.

### BRIEF DESCRIPTION OF THE DRAWINGS

Other objects and features of the invention will become apparent from the following detailed description considered in connection with the accompanying drawings. It is to be understood, however, that the drawings are designed as an illustration only and not as a definition of the limits of the invention.

In the drawings,

FIG. 1 shows a side view of a cooling device with a component to be cooled;

FIG. 2 shows an oblique view of a cooling device;

FIG. 3 shows a side view of an embodiment variant of a cooling device;

FIG. 4 shows a further embodiment variant of a cooling device as seen from below;

FIG. 5 shows an oblique view of a further embodiment variant of a cooling device seen from below;

FIG. 6 shows an embodiment variant of a preform; and

FIG. 7 shows an embodiment variant of a tool for producing the cooling device.

### DETAILED DESCRIPTION OF PREFERRED EMBODIMENTS

By way of introduction, it should be noted that in the various embodiments described, the same parts are provided with the same reference signs or the same component designations, wherein the disclosures contained in the entire description can be transferred analogously to the same parts with the same reference signs or the same component designations. Moreover, the specifications of location, such as at the top, at the bottom, at the side, chosen in the description refer to the directly described and depicted figure and in case of a change of position, these specifications of location are to be analogously transferred to the new position.

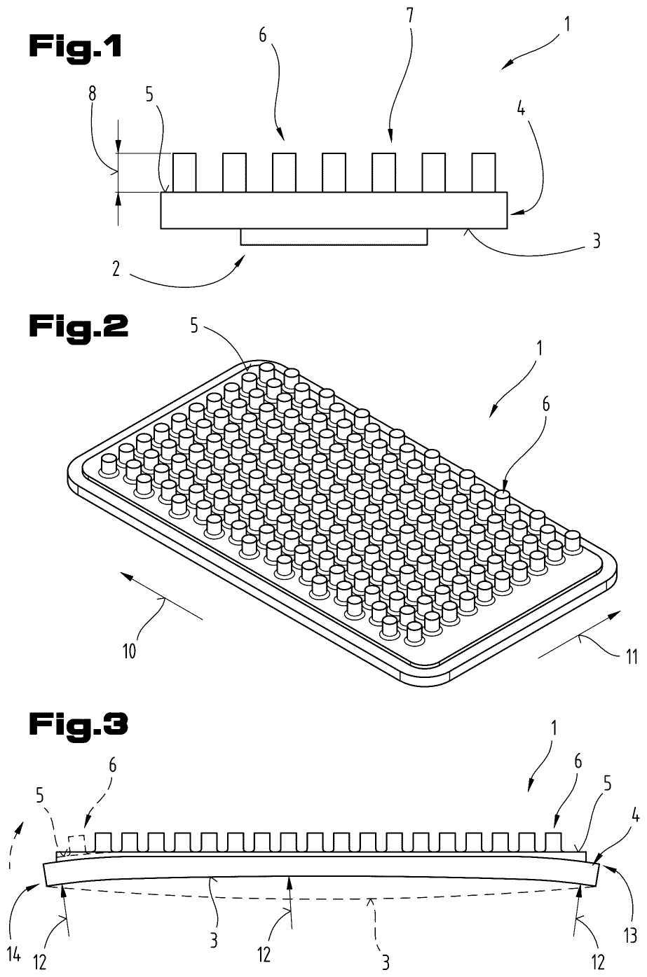

FIG. 1 shows a side view of a cooling device 1.

The cooling device 1 is used to cool a component 2 or several components 2 or an assembly. For this purpose, the cooling device abuts with a second surface 3 forming the rear side against the at least one component 2, in particular directly, and is therefore preferably in direct contact with the component 2 for heat exchange.

The component 2 is preferably an electronic component, in particular a so-called power electronics component or high-performance electronics component or a power semiconductor or high-performance semiconductor. In particular, such components 2 or assemblies made of/with these components 2 may be designed for a power output in the range from several kW up to MW. Such components 2 are used, for example, to convert electrical energy with switching electronic components. Typical applications include converters or frequency converters in the field of electrical drive technology, solar inverters and converters for wind turbines for feeding regeneratively generated energy into the grid or switching power supplies, generally the conversion of AC voltage into DC voltage by rectifiers, the conversion of DC voltage into AC voltage by inverters, control systems, for example in the drive technology of an electric drive in electric vehicles or hybrid vehicles, battery management systems, etc. A power electronics component may, for example, be a semiconductor, in particular a so-called power semiconductor, e.g. an insulated-gate bipolar transistor (IGBT).

Since such components 2 are known in the prior art, reference is made to this prior art in order to avoid repetition of further details.

The cooling device 1 comprises a base element 4, which also forms the rear side of the cooling device 1, and which has a cooling structure on a first surface 5, or consists of the base element 4 and the cooling structure. The cooling structure is formed by cooling elements 6, which are arranged projecting over the first surface 5 on the base element 4 and are integrally connected to it, as may also be seen in FIG. 2. In other words, in the preferred embodiment variant, the cooling device is formed by only one single piece. Irrespective of this one-piece nature, it is possible within the scope of the invention that several cooling devices 1 may be combined with one another per component 2 or assembly of/with at least one such component 2 to form a cooling device group according to the invention. In particular, the cooling devices 1 may therefore also be assembled in a modular way to form a cooling device group.

The base element 4 and the cooling elements 6 are made of or consist of a sinter material. Furthermore, the cooling elements 6 are produced from the base element 4 by forming.

In the preferred embodiment variant, the base element 4 and the cooling elements 6 have a density of at least 98%, in particular at least 98.5%, preferably at least 99%, of the full density of the material used.

The full density refers to the density of a cooling device made from the same material using melting metallurgy, i.e. a component made from a solid material. The term solid material refers to a metallic material that, with the exception of imperfections, has no pores, as is usually the case with sintered components.

The cooling elements 6 are designed to be surrounded by a cooling fluid, for example water, so that the heat absorbed by the cooling device 1 is removed via this cooling fluid. Preferably, the cooling device 1 is a so-called pin fin cooling device.

The cooling elements 6 of the embodiment variant shown are cylindrical. However, they may also have a different shape, for example a truncated cone shape or generally one with a cross-section that tapers in the direction of a cooling element head 7, for example a truncated pyramid shape. The cooling elements 6 may also have a cross-section that widens in the direction of the cooling element head 7, for example in the shape of a mushroom. This may be achieved without machining by pressing on the cooling element heads 7 after the cooling elements 6 have been formed, for example in the course of height calibration of the cooling elements 6.

The cross-section of the cooling elements 6 may be circular, oval, diamond-shaped, square, etc.

Furthermore, all cooling elements 6 may have the same configuration. However, it is also possible to arrange or combine cooling elements 6 with different shapes on a base element 4.

The cooling elements 6 may preferably have a height 8 above the first surface 5 of the base element 4, which is between 2 mm and 20 mm.

In the simplest embodiment of the cooling device 1, all cooling elements 6 of the cooling device 1 have the same height 8 within the tolerances. However, it is possible within the scope of the invention for some of the cooling elements 6 to have a lower height than the remaining cooling elements 6.

Furthermore, it may be provided that between 300 and 1300, in particular between 300 and 1000, for example between 300 and 750, cooling elements 6 are arranged or configured per dm² of the first surface. In particular, this number has proven to be advantageous with regard to the production of the cooling device 1, i.e. the forming of the base element 4 to the cooling elements 6, as damage to the cooling elements 6 or incompletely formed cooling elements 6 may thus be avoided or reduced.

FIG. 3 shows a side view of an embodiment variant of the cooling device 1. This again is provided with the base element 4, on the first surface 5 of which the cooling structure with the cooling elements 6 is arranged.

In contrast to the embodiment variant of the cooling device 1 according to FIG. 1, in this embodiment variant according to FIG. 3 the rear side of the base element 4, i.e. the second surface 3 is provided with a curvature, wherein the base element 4 is prestressed by the production of the curvature.

In the embodiment variant shown, the curvature in relation to the cooling elements 6 has a concave progression. In particular, the base element 4 may have plano-concave configuration. However, as may be seen from the stroke-dotted line in FIG. 3 for the first surface 5, the first surface may also be configured to at least approximately follow the course of the second surface 3 (the rear of the base element 4).

As further indicated by stroke-dotted lines in FIG. 3, at least the second surface 3 or the entire base element 4 may have a convex curvature in relation to the cooling elements 6.

Preferably, the curvature is configured along a length 10 (see FIG. 1) of the base element 4. However, it may also be configured along a width 11 of the base element 4.

The curvature may be configured with a radius of curvature 12 that remains constant over the entire course. According to a further embodiment variant, it may be provided that the curvature has several different radii of curvature 12. In particular, it may be provided that the base element 4 is provided with the curvature with the smallest radius of curvature 12 in opposite edge areas 13, 14.

Preferably, the curvature has a symmetrical configuration from the first edge area 13 to the second edge area 14. However, it may also have an asymmetrical shape.

The curvature may, for example, have an elliptical, parabolic, etc. shape. Other shapes are also conceivable.

The cooling elements 6 may be arranged with the same orientation on the curved base element 4, as shown in full lines in FIG. 3. This may be the case in particular if the base element has a plano-concave configuration. However, the orientation of the cooling elements 6 may also follow the course of the curvature of the base element 4, as indicated in FIG. 3 by a cooling element 6 shown in the left-hand section of the image in stroke-dotted lines. This orientation may be changed in the course of configuring the substance bonding with the component 2 due to the stress relief in the base element 4 as a result of the heat acting on it, when the curvature of the base element 4 is reduced and, in particular, it is configured to a flat base element 4. This is indicated by a stroke-dotted arrow on the left in FIG. 3.

It is also possible for the heights 8 of the cooling elements 6 to be adapted to the curvature so that the cooling element heads 7 are at the same height when the base element 4 is provided with the curvature.

The radius of curvature 12 of the base element 4 may be selected from a range of 250 mm to 5000 mm, in particular from 1000 mm to 4000 mm. A maximum deflection of 1.25 mm over a length of 100 mm or 200 mm can thus be achieved. If the curvature has several different radii of curvature 12, all radii of curvature 12 are preferably also selected from this range.

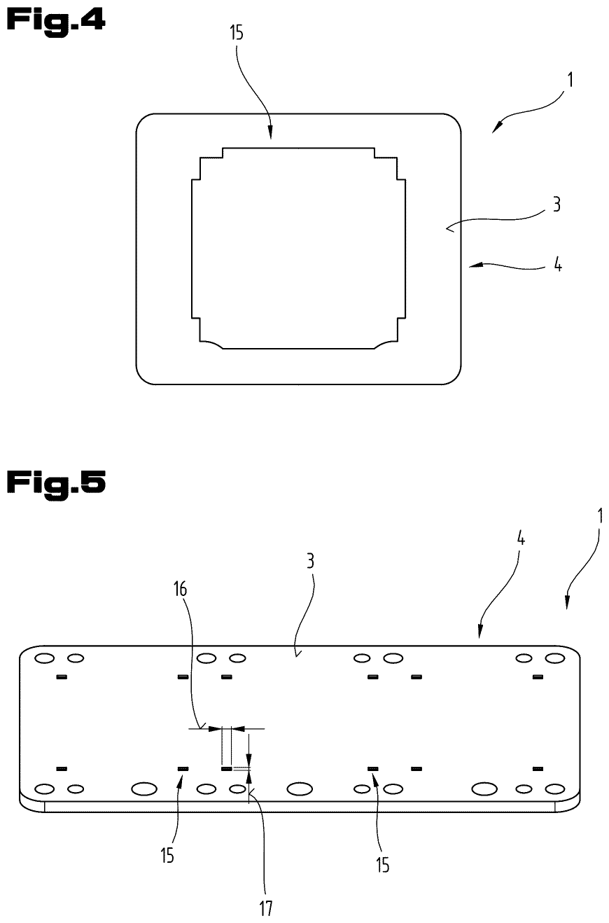

FIG. 4 shows a further embodiment variant of the cooling device 1 as seen from below.

It should be mentioned at this point that the embodiment variants of the cooling device 1 described for FIGS. 3, 4 and 5 may be used independently on their own. Combinations of these embodiment variants are also possible. Therefore, if reference is made below to a flat base element 4, this may also have a curved configuration, as described for FIG. 3.

FIG. 4 shows the flat second surface 3 of the rear side of the base element 4 (see also FIG. 1). At least one auxiliary element 15 is arranged on this rear side to create a substance bonding between the cooling device and the component 2. In the specific embodiment variant shown, the auxiliary element 15 is a depression. However, the auxiliary element 15 may also be a protrusion on the second surface 3, as shown in the embodiment variant shown in FIG. 5.

The depression is used to hold the filler material for the substance bonding and prevents the molten filler material from running out during the configuration of the substance bonding between the cooling device 1 and the component 2 (see FIG. 1).

The protrusion, on the other hand, serves to form a gap, in particular a uniform gap, between the cooling device 1 and the component 2, so that the filler material is configured over the connection surface (the surface to which the filler material is applied) with an at least approximately uniform layer thickness, so that there are as few differences as possible in the thermal resistance between the cooling device 1 and the component 2 over the connection surface.

It should be mentioned at this point that the substance bonding may, in principle, be configured as an adhesive connection. In the preferred embodiment of the invention, however, this is a soldered connection and the filler material is a solder. In particular, the cooling device 1 is connected to the component 2 however not by means of a sinter soldering process.

In FIG. 4, only one auxiliary element 15 is shown. However, more than one auxiliary element 15 may also be arranged, for example two, three, four, etc., as may be seen in FIG. 5. However, the number of auxiliary elements 15 specifically shown in FIG. 5 is not to be understood as limiting the invention. In particular, their number may depend on the size of the base element 4.

Furthermore, the multiple auxiliary elements 15 are not limited to protrusions. Several discrete depressions distributed over the second surface 3 may also be provided as auxiliary elements 15.

Combinations of depressions and protrusions as auxiliary elements 15 on the second surface 3 of the base element 4 are also possible within the scope of the invention.

In top view, the depressions may have a circular, elliptical, oval, generally round, triangular, square, pentagonal, etc. configuration. More complex shapes are also possible, as may be seen from the example of a depression in FIG. 4.

For the above reasons, the recess may have a maximum depth of between 0.05 mm and 0.5 mm.

Preferably, if there are several depressions on the rear side of the base element 4, they are all configured in the same way. However, several differently configured depressions may also be provided.

For the above reasons, the at least one protrusion may have a maximum height of between 0.05 mm and 0.5 mm. If there are several depressions, they may all have the same configuration. Likewise, differently shaped protrusions may be provided on the second surface 3 of the base element 4.

The protrusion or protrusions may have a nub-shaped, web-shaped, etc., configuration. They may, for example, have a round, oval, elliptical, generally round, triangular, square, etc., cross-section when viewed from above.

The protrusion may have a length 16 of between 0.5 mm and the total length of the base element 4. Furthermore, the protrusion may have a width 17 of between 0.5 mm and the total width of the base element 4.

The depression or depressions may have a total surface area of between 0.1% and 50% of the surface area of the second surface 3 of the base element 4.

The base element 4 may have a thickness of between 1 mm and 3 mm, although greater thicknesses of up to 5 mm are also conceivable.

The connection layer between the cooling device 1 and the component 2 may have a layer thickness of between 0.01 mm and 0.5 mm.

According to a further embodiment variant, it may be provided that the base element 4 and the cooling elements 6 consist of a sinter material and that the cooling elements 6 are produced by forming from the material of the base element 4, as described below.

The at least one auxiliary element 15 may also be produced by powder metallurgy and may be configured in one piece with the base element 4.

A sintering powder or a powder used in powder metallurgy, in particular a metallic powder, is used to produce the cooling device 1. Preferably, a sintering powder is used that has a correspondingly good thermal conductivity. In particular, a sintering powder based on aluminum or an aluminum alloy or based on copper or a copper alloy or a MMC (metal matrix composite) sintering powder is used.

The cooling device 1 is produced by powder metallurgy using a powder metallurgy method, so it is preferred that the cooling device 1 is a sintered component. For this purpose, a green compact is produced in a corresponding press mold (die) from a powder, which may be produced from the individual (metallic) powders by mixing, wherein the powders may be used pre-alloyed if necessary. Preferably, the green compact has a density of at least 80%, in particular between 80% and 96%, of the full density of the material.

The green compact is then dewaxed at normal temperatures and sintered in one or two stages or in several stages and then cooled, preferably to room temperature. Sintering may take place at a temperature between 500° C. and 1300° C., for example.

Since these methods and the method parameters used are also known from the prior art, reference is made to the relevant prior art in order to avoid repetition.

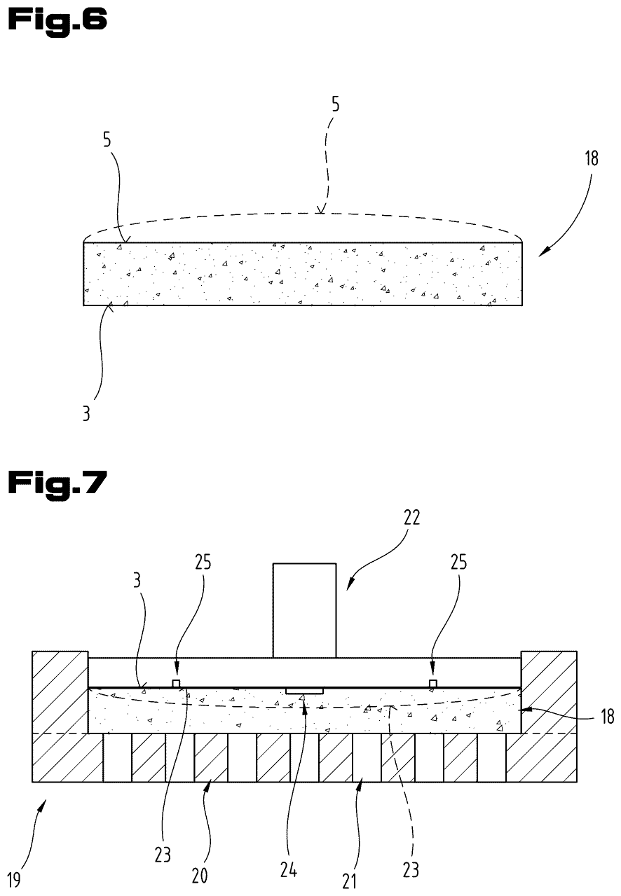

Sintering produces a preform 18 from the green compact, as shown as an example in FIG. 6. The preform 18 may be configured as a flat plate, so that the second surface 3 and the first surface 5 run parallel to each other.

According to an embodiment variant of the method, it may be provided that the first surface 5 of the preform 18, on which the cooling structure is configured, is produced curved at least in portions, as indicated by a stroke-dotted line in FIG. 6. Other shapes of the first surface of the preform 18 are possible with regard to improved formability of the preform 18. This means that the first pin fin projections or cooling element projections (circular, oval, elliptical, etc.) with a height of between 0.1 mm and 2.0 mm may already be preformed. In addition, structures (waves, ribs, etc.) may be deliberately introduced into the first surface 5 of the preform 18 in order to increase the turbulence of a cooling fluid if necessary.

The preform 18 may subsequently be recompressed. Preferably, however, the recompression takes place at the same time as the preform 18 is formed to the cooling elements 6.

The forming of the preform 18 is realized in a mold 19. For this purpose, the preform 18 is inserted into or placed against the mold 19. In the simplest case, the mold 19 is formed by a perforated plate 20. The perforated plate 20 has recesses 21, in particular apertures, into or through which some of the material of the preform 18 is pressed, forming the cooling elements 6. The rest of the material of the preform 18, which is not pressed into or through the mold 19, forms the base element 4.

The recesses 21, i.e. their cross-section, are adapted accordingly to the cross-section of the cooling elements 6 to be produced.

The mold 19 may also look different, so it does not necessarily have to be a simple perforated plate 20. In particular, the mold 19 may have a “pot-shaped” configuration as a die.

For the forming process, a punch 22 is applied to the rear side (second surface 3) of the preform 18, which also forms the rear side of the base element 4, and pressed onto the preform 18 with a predeterminable pressure. For example, forming may take place at a pressure of between 700 MPa and 1600 MPa. Furthermore, forming may take place during a time of up to 10 seconds, in particular between 0.1 seconds and 10 seconds. Furthermore, the forming preferably takes place at room temperature (20° C.), i.e. cold, or the forming may also take place after preheating the preform 18 to a temperature between 50° C. and 300° C., for example between 50° C. and 150° C., and/or in/with a mold 19 heated to a temperature between 50° C. and 300° C., for example between 50° C. and 150° C.

After the shaping, i.e. the forming of the preform 18, the cooling device 1 may be finished. However, it is also possible to post-process the cooling device 1. For example, the cooling elements 6 may be height-calibrated or generally recompressed, for which a punch may also be used. In addition, the first surface 5 and the cooling elements 6 may be provided with a corrosion-resistant coating.

The at least auxiliary element 15 may also be produced in the course of post-processing. It may also be produced during powder pressing before sintering. In this case, the punch 22 must have corresponding recesses or protrusions so that the auxiliary elements 15 are not crushed during forming of the preform 18.

In the preferred embodiment variant, however, the at least one auxiliary element 15 is produced at the same time as the preform 18 is formed. For this purpose, the punch 22 may have a protrusion 24 on an abutment surface 23 that may be placed against the preform 18 to form the depression described above in the second surface 3 of the base element 4 and/or a depression 25 to form the protrusion described above on the second surface 3 of the base element 4. The number of protrusions 24 and/or depressions 25 on the punch 22 depends on the number of auxiliary elements 15 to be produced.

It may also be provided that the production of the at least one auxiliary element 15 is carried out during the height calibration of the cooling elements 6. For this purpose, a supporting surface of a mold or a clamping element, on which the base element 4 is placed for height calibration, has the corresponding protrusions 24 or depressions 25.

It should be mentioned at this point that the preform 18 may be formed in one or more stages. In the multi-stage embodiment, the cooling elements 6 are not formed in one step, but in several steps. Particularly in the multi-stage embodiment variant, it may be advantageous if the auxiliary element 15 is formed in the course of any height calibration of the cooling elements 6.

The curvature of the base element 4 described above may also be carried out in the course of forming the preform 18 or in the course of the height calibration of the cooling elements 6 that may have to be carried out. In FIG. 7, a curved abutment surface 23 of the punch 22 is in outlines shown as a stroke-dotted line. The curvature of the abutment surface 23 is inverse to the curvature of the base element 4 to be produced. This means that no machining is required to configure the curvature of the base element 4.

The exemplary embodiments show possible embodiment variants, wherein it should be noted at this point that combinations of the individual embodiment variants with one another are also possible.

Finally, for the sake of order, it should be noted that for a better understanding of the structure of the cooling device 1 or the mold 19, these are not necessarily shown to scale.

Although only a few embodiments of the present invention have been shown and described, it is to be understood that many changes and modifications may be made thereunto without departing from the spirit and scope of the invention.

### REFERENCE SIGNS LIST

1 cooling device
2 component
3 surface
4 base member
5 surface
6 cooling element
7 cooling element head
8 height
9 structural element
10 length
11 width
12 curvature radius
13 edge area
14 edge area
15 auxiliary element
16 length
17 width
18 preform
19 mold
20 perforated plate
21 recess
22 punch
23 abutment area
24 protrusion
25 depression

What is claimed is:

1. A cooling device (1) for cooling a component (2), comprising a base element (4) having a first surface (5) and a second surface (3) which is opposite the first surface (5) and forms a rear side, and having a cooling structure which has cooling elements (6) and is arranged on the base element (4) so as to project beyond the first surface (5), wherein the rear side of the base element (3) is configured with a curvature and has a prestress and/or wherein at least one auxiliary element (15) is arranged on the rear side for producing a substance bonding between the cooling device (1) and the component (2).

2. The cooling device (1) according to claim 1, wherein the curvature is a concave curvature of the base element (4) in relation to the cooling elements (6), in particular that the base element (4) has a plano-concave configuration.

3. The cooling device (1) according to claim 2, wherein the concave curvature has several different radii of curvature (12).

4. The cooling device (1) according to claim 3, wherein the base element (4) has the curvature with the smallest radius of curvature (12) in opposite edge areas (13, 14).

5. The cooling device (1) according to claim 1, wherein the auxiliary element (15) is a depression in the second surface (3).

6. The cooling device (1) according to claim 5, wherein the depression has a maximum depth of between 0.05 mm and 0.5 mm.

7. The cooling device (1) according to claim 1, wherein the auxiliary element (15) is a protrusion on the second surface (3).

8. The cooling device (1) according to claim 7, wherein the protrusion has a maximum height of between 0.05 mm and 0.5 mm.

9. The cooling device (1) according to claim 1, wherein the base element (4) and the cooling elements (6) comprise a sinter material and wherein the cooling elements (6) are produced by forming from the material of the base element (4).

10. The cooling device (1) according to claim 1, wherein the auxiliary element (15) is produced by powder metallurgy in one piece with the base element (4).

11. A method for producing a cooling device (1) comprising the steps of providing a material and configuring a cooling structure from the material, wherein a sintering powder is used as the material, from which a green compact is produced by pressing, wherein the green compact is sintered to form a preform (18), and wherein the cooling structure in the form of cooling elements (6) is produced from the preform (18) by forming, for which purpose a part of the preform (18) is pressed through a mold (19), and wherein a rear side of the base element (4) is produced in a prestressed configuration with a curvature and/or wherein at least one auxiliary element (15) is arranged on the rear side for the production of a substance bonding between the cooling device (1) and a component (2).

12. The method according to claim 11, wherein the cooling elements (6) are calibrated in height after the preform (18) has been formed.

13. The method according to claim 12, wherein the curvature of the rear side of the base element (4) is configured during the height calibration.

14. The method according to claim 11, wherein the auxiliary element (15) is configured on the rear side of the base element (4) for producing a substance bonding during the forming of the preform (18).
